(19) United States
(12) Patent Application Publication
(10) Pub. No.: US 2026/0031811 A1
(43) Pub. Date: Jan. 29, 2026

(54) SIGNAL TRANSMISSION DEVICE AND SWITCHING DEVICE

(71) Applicant: ROHM CO., LTD., Kyoto-shi (JP)

(72) Inventors: Koshiro NAGASATO, Kyoto-shi (JP); Koki MISHIMA, Kyoto-shi (JP)

(21) Appl. No.: 19/271,916

(22) Filed: Jul. 17, 2025

(30) Foreign Application Priority Data
Jul. 24, 2024 (JP) 2024-118483

(51) Int. Cl. H03K 17/691; H03K 17/0812; H03K 17/693

(52) U.S. Cl. CPC H03K 17/691; H03K 17/08122; H03K 17/693

(57) ABSTRACT

A signal transmission device includes a primary side circuit that receives a primary side control signal from the external device, a secondary side circuit that drives a gate of the target transistor, and an insulation circuit that transmits a primary side control signal as a secondary side control signal to the secondary side circuit in an insulation form. The secondary side circuit is configured to control a gate voltage of the target transistor in accordance with the secondary side control signal so as to switch the target transistor between ON and OFF, and to be capable of adjusting a slew rate of change of the gate voltage of the target transistor in multiple steps. The secondary side circuit generates temperature information according to temperature of the target transistor, and compares the temperature information with reference information, so as to adjust the slew rate.

### CROSS REFERENCE TO RELATED APPLICATIONS

The present invention claims priority under 35 U.S.C. § 119 to Japanese Patent Application No. 2024-118483 filed Jul. 24, 2024, the entire contents of which are hereby incorporated by reference.

### BACKGROUND OF THE INVENTION

### Field of the Invention

The present disclosure relates to a signal transmission device and a switching device.

### Description of Related Art

A device that drives a gate of a target transistor responding to a control signal is widely used (see Patent Document 1).
Patent Document 1: JP-A-2018-14549

### BRIEF DESCRIPTION OF THE DRAWINGS

FIG. 1 is a diagram illustrating the basic configuration of a signal transmission device.

FIG. 2 is a diagram illustrating the basic structure of a transformer chip.

FIG. 3 a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a structural diagram of a signal transmission device according to an application structure.

FIG. 11 is an overall structural diagram of a system including the signal transmission device according to the application structure.

FIG. 12 is an external perspective view of the signal transmission device of FIG. 11.

FIG. 13 is a waveform chart of two control signals in the signal transmission device of FIG. 11.

FIG. 14 is an explanatory diagram of a state and a drive condition for driving a gate of a target transistor.

FIG. 15 is an explanatory diagram of a state and a drive condition for driving the gate of the target transistor.

FIG. 16 is an explanatory diagram of a relationship between temperature and a slew rate of a gate voltage of the target transistor.

FIG. 17 is a diagram illustrating a manner in which a plurality of temperature ranges are determined by setting a plurality of boundary temperatures.

FIG. 18 is a diagram illustrating a manner in which two temperature ranges are determined by setting one boundary temperature.

FIG. 19 is a diagram illustrating a structure of a temperature determination circuit and a structure of its vicinity, according to a first embodiment of the present disclosure.

FIG. 20 is a diagram illustrating a relationship among a temperature of the target transistor, a detection voltage, and a temperature determination signal, according to the first embodiment of the present disclosure.

FIG. 21 is a diagram illustrating a structure of the temperature determination circuit and a structure of its vicinity, according to a second embodiment of the present disclosure.

FIG. 22 is a diagram illustrating a relationship among the temperature of the target transistor, a detected digital value, and the temperature determination signal, according to the second embodiment of the present disclosure.

FIG. 23 is an operational flowchart of the signal transmission device according to the second embodiment of the present disclosure.

FIG. 24 is a structural diagram of a system including a switching device according to a fourth embodiment of the present disclosure.

### DETAILED DESCRIPTION OF THE PREFERRED EMBODIMENTS

### <Signal Transmission Device (Basic Configuration)>

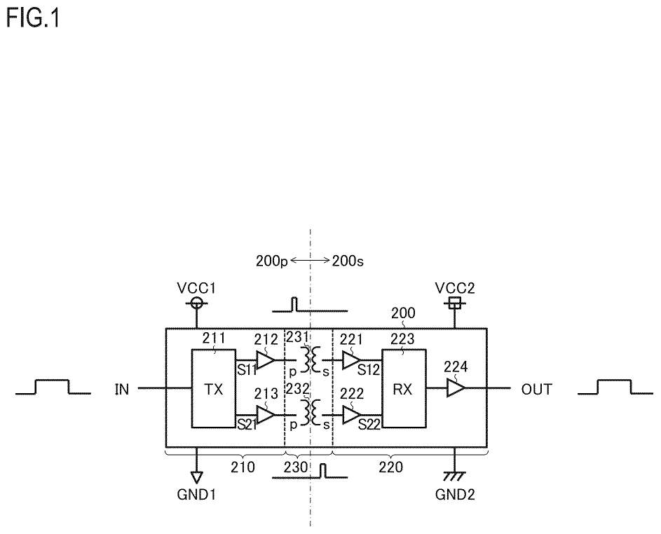

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drivers the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### <Transformer Chip (Basic Structure)>

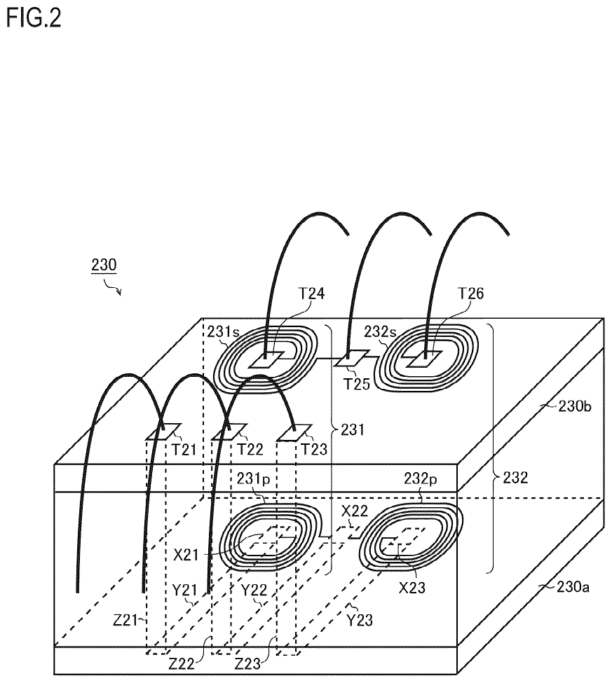

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 231s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### <Transformer Chip (Two-Channel Type)>

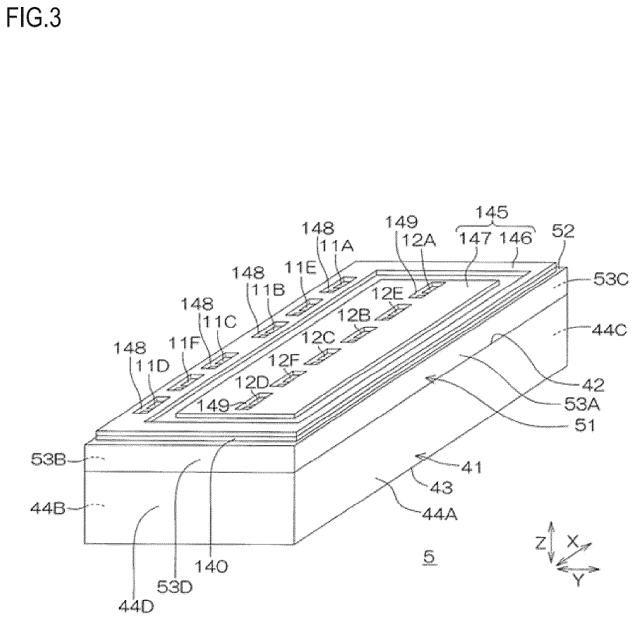

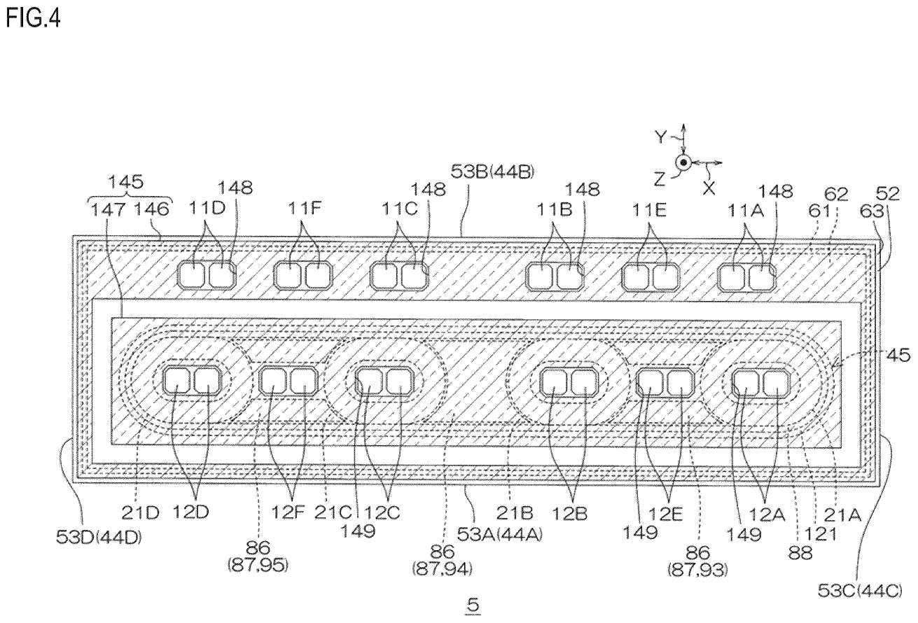

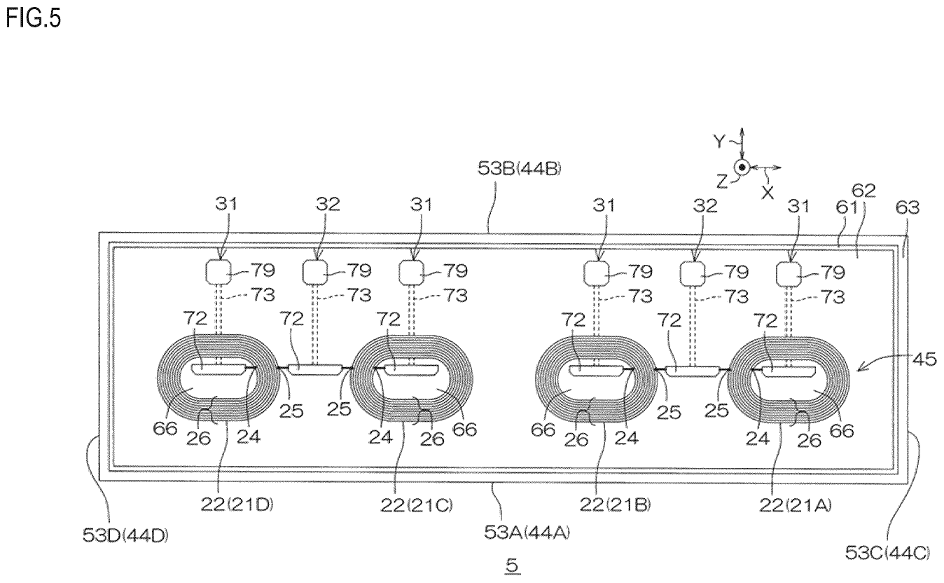

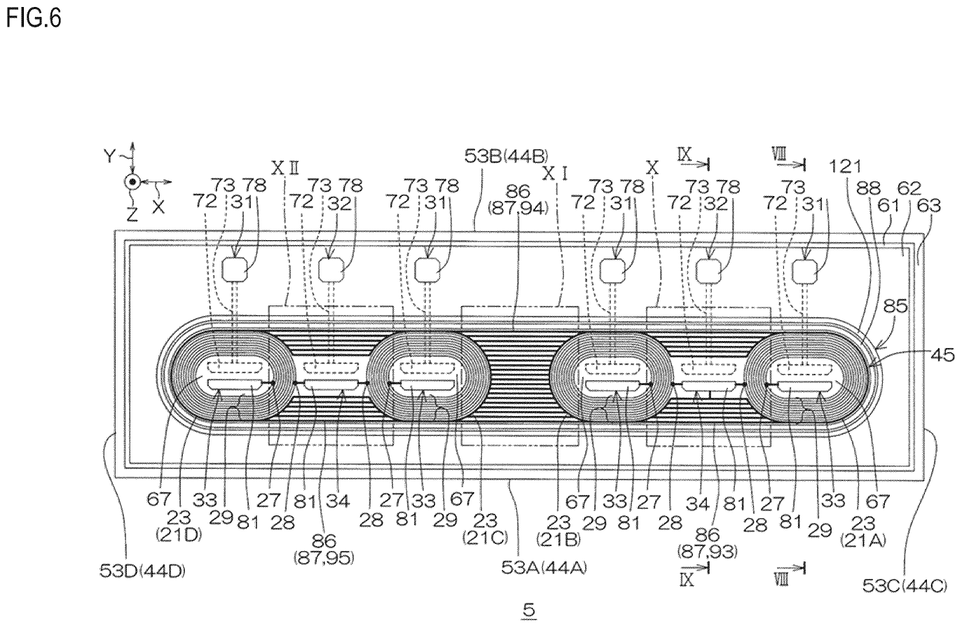

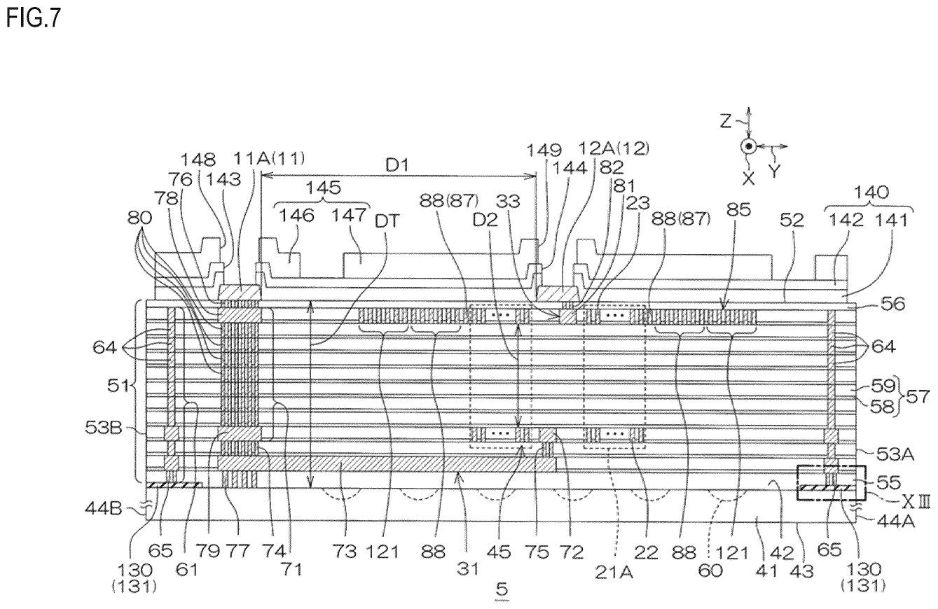

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D includes a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low- and high-potential coils 22 and 23 are formed in a region between the bottom and top insulation layers 55 and 56 (i.e., in the plurality of interlayer insulation layer 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low- and high-potential coils 22 and 23 can be disposed at any places. The high-potential coil 23 can face the low-potential coil 22 across one or more interlayer insulation layers 57.

The distance between the low- and high-potential coils 22 and 23 (i.e., the number of interlayer insulation layers 57 stacked together) is adjusted appropriately according to the dielectric strength voltage and electric field strength between the low- and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The body layer is embedded in a recessed space defined by the barrier layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layer 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73 and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71 and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low- and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81 and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low- and high-potential terminals 11 and 12 is larger than the distance D2 between the low- and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high- and low-potential coils 23 and 22 and is independent of the transformers 21A to 21D. That is, the dummy pattern 85 does not function as part of the transformers 21A to 21D. The dummy pattern 85 is formed as a shield conductor layer that shields electric fields between the low- and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of +20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low- and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D. In the embodiment, the sealing conductor 61 is formed in a quadrangular ring shape (specifically, a rectangular ring shape) as seen in a plan view. Thus, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductor 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

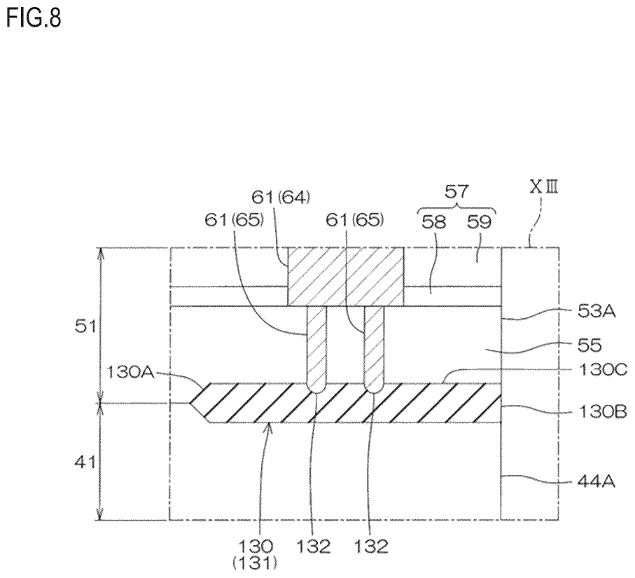

Referring FIG. 7 and FIG. 8, the semiconductor device 5 further includes a separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41 and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41 and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61 and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low- and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlapping parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with a first embodiment (except those associated with the dummy pattern 85).

That is, in a case where a voltage is applied to the second functional device 60 via the low- and high-potential terminals 11 and 12, it is possible suppress unnecessary conduction between the high-potential terminal 12 and the sealing conductor 61. Likewise, in a case where a voltage is applied to the second functional device 60 via the low- and high-potential terminals 11 and 12, it is possible suppress unnecessary conduction between the low-potential terminal 11 and the sealing conductor 61.

The embodiment described above deals with an example where a second functional device 60 is formed. The second functional device 60, however, is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### <Transformer Layout>

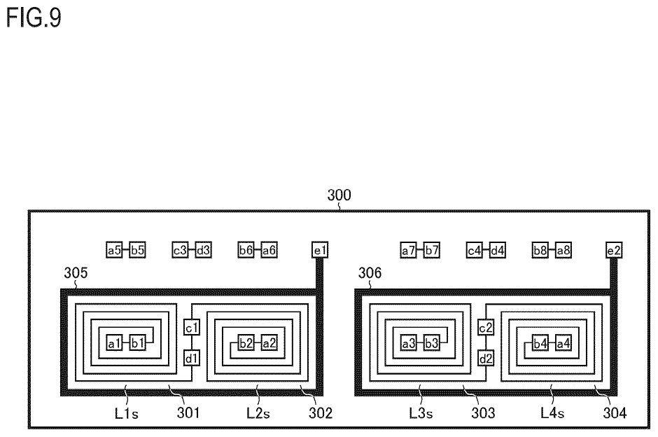

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 302, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### <Signal Transmission Device (Application Structure)>

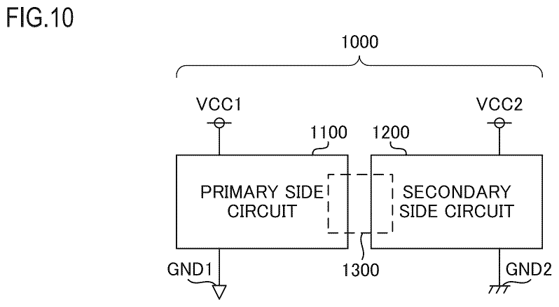

FIG. 10 illustrates a structural diagram of a signal transmission device 1000. The signal transmission device 1000 is a signal transmission device according to an application structure and may be formed by utilizing the structure of the signal transmission device 200 described above (see FIG. 1 and the like). The signal transmission device 1000 may also be considered as one form of the signal transmission device 200.

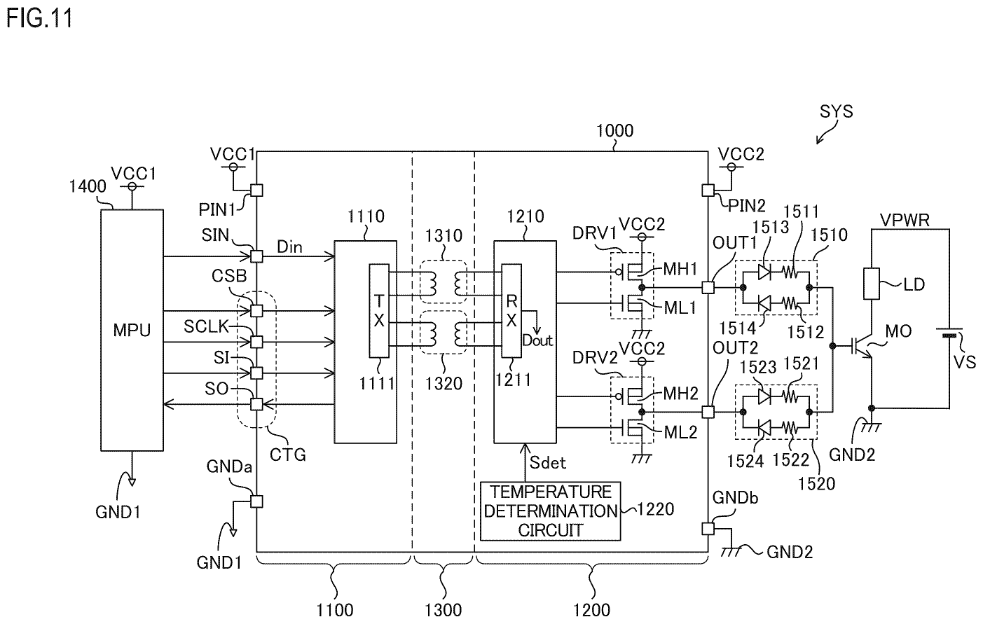

Note that in this specification, for simple description, by writing a symbol or code representing information, signal, physical quantity, functional section, circuit, element, component, or the like, a name of the information, signal, physical quantity, functional section, circuit, element, component, or the like corresponding to the symbol or code may be abbreviated or shortened. For instance, a first signal processing circuit denoted by “1110” described later (see FIG. 11) may be referred to as a first signal processing circuit 1110 or may be referred to as a signal processing circuit 1110, which indicate the same one.

Some terms and expressions are described below. A level means a level (height) of a potential (electric potential), and for an arbitrary noted signal or voltage, high level has a higher potential than low level. In an arbitrary noted signal or voltage, switching from low level to high level may be referred to as a rising edge, and switching from high level to low level may be referred to as a falling edge.

For an arbitrary transistor constituted as a field-effect transistor (FET) such as a MOSFET, ON state means a state where the transistor is conducting between the drain and source, while OFF state means a state where the transistor is nonconducting (cut off) between the drain and source of the transistor. The same is true for a transistor (such as an IGBT) that is not classified as an FET. A MOSFET is understood to be an enhancement type MOSFET, unless otherwise noted. MOSFET is an abbreviation of “metal-oxide-semiconductor field-effect transistor”. In addition, unless otherwise noted, in an arbitrary MOSFET, it may be considered that the backgate is short-circuited to the source. Hereinafter, for an arbitrary transistor, ON state and OFF state may be simply expressed as ON and OFF. In addition, for an arbitrary transistor, a period during which the transistor is in ON state is referred to as an ON period, while a period during which the transistor is in OFF state is referred to as an OFF period.

For an arbitrary signal having a signal level of high level or low level, a period during which the level of the signal is high level is referred to as a high level period, while a period during which the level of the signal is low level is referred to as a low level period. The same is true for an arbitrary voltage having a voltage level of high level or low level.

Connection between a plurality of parts forming a circuit, such as arbitrary circuit elements, wirings, and nodes, may be understood to mean electric connection, unless otherwise noted.

When arbitrary two voltages to be compared are voltages v1 and v2, “v1>v2” means that the voltage v1 is higher than the voltage v2, “v1<v2” means that the voltage v1 is lower than the voltage v2, and “v1=v2” means that the value of the voltage v1 is the same as the value of the voltage v2. The same is true for other expressions including a physical quantity other than voltage.

As illustrated in FIG. 10, the signal transmission device 1000 includes a primary side circuit 1100 and a secondary side circuit 1200. The signal transmission device 1000 is provided with an insulation circuit 1300 including a plurality of insulation elements. The primary side circuit 1100 and the secondary side circuit 1200 are insulated from each other. Each of the insulation elements in the insulation circuit 1300 is disposed between the primary side circuit 1100 and the secondary side circuit 1200. The insulation circuit 1300 is a circuit that insulates in a DC manner between the primary side circuit 1100 and the secondary side circuit 1200, while transmitting a signal in the primary side circuit 1100 to the secondary side circuit 1200. A power supply source for the transmission is the primary side circuit 1100, and hence in detail, the primary side circuit 1100 drives the insulation elements in the insulation circuit 1300 so that a signal in the primary side circuit 1100 is transmitted to the secondary side circuit 1200.

The primary side circuit 1100 and the secondary side circuit 1200 respectively correspond to the primary circuit system 200p and the secondary circuit system 200s of FIG. 1. It may be considered that the primary side circuit 1100 is one form of the primary circuit system 200p, and that the secondary side circuit 1200 is one form of the secondary circuit system 200s. The primary side circuit 1100 can be formed of the controller chip 210 (see FIG. 1 and the like), and the secondary side circuit 1200 can be formed of the driver chip 220 (see FIG. 1 and the like). The insulation circuit 1300 can be formed of the transformer chip 230 (see FIG. 1 and the like).

A ground in the primary side circuit 1100 is referred to as a ground GND1. The ground GND1 has a reference potential in the primary side circuit 1100. A conductor part having the reference potential in the primary side circuit 1100 is the ground GND1. In the primary side circuit 1100, a voltage shown without a specific reference indicates a potential with respect to the ground GND1. A power supply voltage VCC1 (see FIG. 1, too) is supplied to the primary side circuit 1100. The primary side circuit 1100 is driven on the basis of the power supply voltage VCC1, with respect to the potential of the ground GND1.

A ground in the secondary side circuit 1200 is referred to as a ground GND2. The ground GND2 has a reference potential in the secondary side circuit 1200. A conductor part having the reference potential in the secondary side circuit 1200 is the ground GND2. In the secondary side circuit 1200, a voltage shown without a specific reference indicates a potential with respect to the ground GND2. A power supply voltage VCC2 (see FIG. 1, too) is supplied to the secondary side circuit 1200. The secondary side circuit 1200 is driven on the basis of the power supply voltage VCC2, with respect to the potential of the ground GND2. The ground GND1 and the ground GND2 are insulated from each other.

FIG. 11 illustrates an overall structure of a system SYS including the signal transmission device 1000. The system SYS is provided with, in addition to the signal transmission device 1000, a microprocessor unit (MPU) 1400, resistor circuits 1510 and 1520, a target transistor MO, a load LD, and a voltage source VS. The target transistor MO is an N-channel type insulated gate bipolar transistor (IGBT). However, an N-channel type MOSFET may be used as the target transistor MO. The signal transmission device 1000 has a function of driving the gate of the target transistor MO, and the signal transmission device 1000 can be referred to as a gate driving device (insulation gate driver). The MPU 1400 is an example of an external device disposed outside of the signal transmission device 1000. The signal transmission device 1000 is disposed between the MPU 1400 and the target transistor MO.

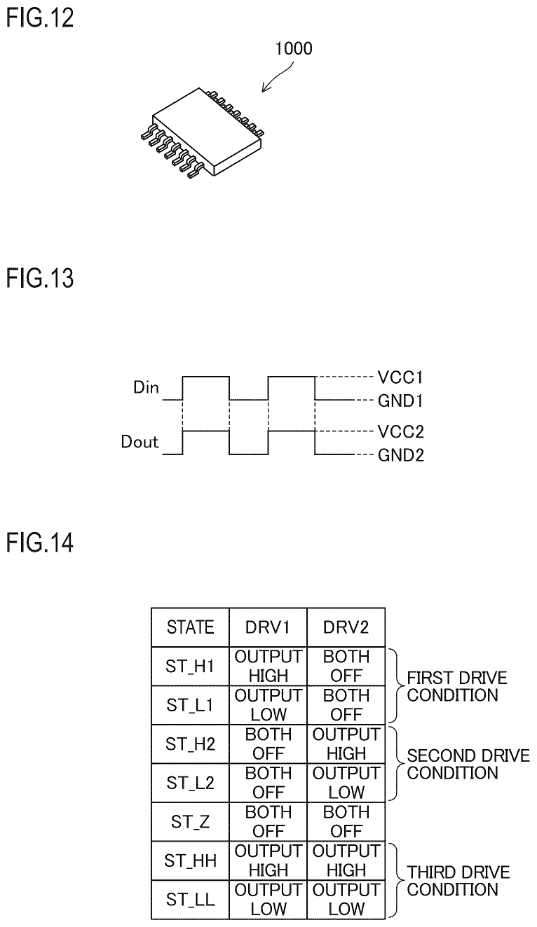

FIG. 12 is an external perspective view of the signal transmission device 1000. The signal transmission device 1000 is an electronic component (semiconductor device) equipped with a plurality of semiconductor chips, a case (package) housing the plurality of semiconductor chips, and a plurality of external terminals exposed from the case to the outside of the signal transmission device 1000. The plurality of semiconductor chips are sealed in the case (package) made of resin, and thus the signal transmission device 1000 is formed. Note that the number of the external terminals of the signal transmission device 1000 and a type of the case of the signal transmission device 1000 illustrated in FIG. 12 are merely an example, and they can be arbitrarily designed. FIG. 11 illustrates power supply terminals PIN1 and PIN2, a signal input terminal SIN, terminals CSB, SCLK, SI and SO as communication terminals, ground terminals GNDa and GNDb, and output terminals OUT1 and OUT2, as a part of the plurality of external terminals provided to the signal transmission device 1000. Other external terminals are also provided to the signal transmission device 1000.

A not-shown external voltage source supplies the power supply voltage VCC1 to the power supply terminal PIN1. Another not-shown external voltage source supplies the power supply voltage VCC2 to the power supply terminal PIN2. The ground terminal GNDa is connected to the ground GND1. The ground terminal GNDb is connected to the ground GND2. The MPU 1400 is driven on the basis of the power supply voltage VCC1 with respect to the ground GND1. The signal input terminal SIN, and the terminals CSB, SCLK, SI and SO are connected to the MPU 1400.

The resistor circuit 1510 is inserted between the output terminal OUT1 and the gate of the target transistor MO. The resistor circuit 1510 has a resistance component that functions as a gate resistance of the target transistor MO. Specifically, the resistor circuit 1510 includes resistors 1511 and 1512, and diodes 1513 and 1514. The output terminal OUT1 is connected to the anode of the diode 1513 and the cathode of the diode 1514. The cathode of the diode 1513 is connected to a first terminal of the resistor 1511, and a second terminal of the resistor 1511 is connected to the gate of the target transistor MO. The anode of the diode 1514 is connected to a first terminal of the resistor 1512, and a second terminal of the resistor 1512 is connected to the gate of the target transistor MO.

The resistor circuit 1520 is inserted between the output terminal OUT2 and the gate of the target transistor MO. The resistor circuit 1520 includes a resistance component that functions as the gate resistance of the target transistor MO. Specifically, the resistor circuit 1520 includes resistors 1521 and 1522, and diodes 1523 and 1524. The output terminal OUT2 is connected to the anode of the diode 1523 and the cathode of the diode 1524. The cathode of the diode 1523 is connected to a first terminal of the resistor 1521, and a second terminal of the resistor 1521 is connected to the gate of the target transistor MO. The anode of the diode 1524 is connected to a first terminal of the resistor 1522, and a second terminal of the resistor 1522 is connected to the gate of the target transistor MO.

The load LD is inserted between an application terminal of a power supply voltage VPWR and the target transistor MO. In the structural example of FIG. 11, the application terminal of the power supply voltage VPWR is connected to a first terminal of the load LD, and a second terminal of the load LD is connected to the collector of the target transistor MO. The emitter of the target transistor MO is connected to the ground GND2. The power supply voltage VPWR has a potential higher than the ground GND2 by a predetermined level. A current loop, which passes the voltage source VS that generates the power supply voltage VPWR with respect to the potential of the ground GND2, the load LD, the target transistor MO, and the ground GND2, is formed. During the ON period of the target transistor MO, a current based on the power supply voltage VPWR flows through the load LD and the target transistor MO (the current flows in the current loop described above). During the OFF period of the target transistor MO, the current through the load LD and the target transistor MO is not generated (the current does not flow in the current loop described above). Note that the ground terminal GNDb is connected to the emitter of the target transistor MO.

The signal transmission device 1000 includes the first signal processing circuit 1110 as a structural element of the primary side circuit 1100, and includes a second signal processing circuit 1210, a temperature determination circuit 1220, and drivers DRV1 and DRV2 as structural elements of the secondary side circuit 1200 and includes transformers 1310 and 1320 as structural elements of the insulation circuit 1300.

The MPU 1400 supplies a control signal Din to the signal input terminal SIN, and the control signal Din from the MPU 1400 is received by the first signal processing circuit 1110 via the signal input terminal SIN. The control signal Din is a control signal in the primary side circuit 1100 and has high level or low level. In the control signal Din, high level has a potential of the power supply voltage VCC1, while low level has the potential of the ground GND1. A waveform shaping circuit such as a Schmitt buffer may be disposed between the signal input terminal SIN and the first signal processing circuit 1110.

The first signal processing circuit 1110 is connected to the MPU 1400 via a communication terminal group CTG consisting of the terminals CSB, SCLK, SI and SO, and it can perform bidirectional communication with the MPU 1400 using the communication terminal group CTG. Note that the communication between the first signal processing circuit 1110 and the MPU 1400 has the same meaning as the communication between the signal transmission device 1000 and the MPU 1400. The communication between the signal transmission device 1000 and the MPU 1400 may be parallel communication, but here, it is supposed that the communication between the signal transmission device 1000 and the MPU 1400 is serial communication, and it is supposed to use a serial peripheral interface (SPI) as an interface for the serial communication. The terminal CSB is a chip select terminal that receives a chip select signal from the MPU 1400. The terminal SCLK is a clock input terminal that receives a clock signal from the MPU 1400. The terminal SI is a data input terminal that receives an input data signal from the MPU 1400. The terminal SO is a data output terminal that outputs an output data signal to the MPU 1400. The chip select signal, the clock signal, and the input data signal are input to the first signal processing circuit 1110. A waveform shaping circuit such as a Schmitt buffer may be disposed between the first signal processing circuit 1110 and each of the terminals CSB, SCLK and SI. The first signal processing circuit 1110 transmits the output data signal to the MPU 1400 via the terminal SO.

A communication interface (not shown), which performs signal transmission and reception according to an SPI protocol, is included in the first signal processing circuit 1110. However, it may also be possible to consider that the communication interface is disposed between the communication terminal group CTG and the first signal processing circuit 1110. Note that the serial communication interface between the signal transmission device 1000 and the MPU 1400 is not limited to the SPI, and therefore it may be possible to use an interface of I²C (Inter-Integrated Circuit) or Microwire, for example.

The first signal processing circuit 1110 includes a transmission circuit 1111. The transmission circuit 1111 is connected to each primary side coil of the transformers 1310 and 1320. The second signal processing circuit 1210 includes a reception circuit 1211. The reception circuit 1211 is connected to each secondary side coil of the transformers 1310 and 1320. Using the transformers 1310 and 1320, the control signal Din is transmitted from the transmission circuit 1111 to the reception circuit 1211 in an insulation form. In other words, the transmission circuit 1111 supplies a transmission pulse signal to each primary side coil of the transformers 1310 and 1320 in accordance with the control signal Din, and the reception circuit 1211 restores the control signal Din on the basis of a reception pulse signal generated across both ends of each secondary side coil of the transformers 1310 and 1320. The restored control signal Din is referred to as a control signal Dout. The control signals Din and Dout are respectively examples of a primary side control signal and a secondary side control signal. The control signal Dout is a control signal in the secondary side circuit 1200 and has high level or low level. In the control signal Dout, high level has a potential of the power supply voltage VCC2, and low level has the potential of the ground GND2. Note that the transformers 1310 and 1320 respectively have the same structure as the transformers 231 and 232 described above (see FIG. 1 and the like). It can also be understood that the transformer 1310 is the transformer 231 itself, and that the transformer 1320 is the transformer 232 itself.

In addition, although not particularly illustrated, it may be possible that the second signal processing circuit 1210 can also transmit a signal to the first signal processing circuit 1110 in an insulation form. In other words, it may be possible to dispose a secondary side transmission circuit having the same structure as the transmission circuit 1111, in the second signal processing circuit 1210, while to dispose a primary side reception circuit having the same structure as the reception circuit 1211, in the first signal processing circuit 1110, and to dispose another transformer that transmits a signal from the secondary side transmission circuit to the primary side reception circuit in an insulation form, in the insulation circuit 1300. Further, if an abnormality is detected in the secondary side circuit 1200, it is possible to transmit an abnormality detection signal indicating that an abnormality has been detected, from the secondary side transmission circuit to the primary side reception circuit via the another transformer described above, and when the first signal processing circuit 1110 receives the abnormality detection signal, it can send a predetermined error signal to the MPU 1400.

FIG. 13 illustrates a relationship between the control signals Din and Dout. In an initial state, the control signals Din and Dout have low level. The transmission circuit 1111 responds to a rising edge of the control signal Din so as to supply a transmission pulse signal (pulse-like current) to the primary side coil of the transformer 1310, thereby generates a reception pulse signal (electromotive force) across both ends of the secondary side coil of the transformer 1310, and the reception circuit 1211 generates a rising edge in the control signal Dout on the basis of the reception pulse signal in the secondary side coil of the transformer 1310. The transmission circuit 1111 responds to a falling edge in the control signal Din so as to supply a transmission pulse signal (pulse-like current) to the primary side coil of the transformer 1320, thereby generates a reception pulse signal (electromotive force) across both ends of the secondary side coil of the transformer 1320, and the reception circuit 1211 generates a falling edge in the control signal Dout on the basis of the reception pulse signal in the secondary side coil of the transformer 1320. The relationship between the level of the control signal Din and the level of the control signal Dout may be opposite to that described above, and here, it is supposed that the reception circuit 1211 is configured so that the control signal Dout has high level in the high level period of the control signal Din, and that the control signal Dout has low level in the low level period of the control signal Din (for simple description, signal delay is omitted).

Note that the insulation circuit 1300 has an arbitrary structure, as long as the secondary side circuit 1200 can obtain the control signal Dout described above, by transmitting the control signal Din to the secondary side circuit 1200 in an insulation form. Therefore, the insulation element in the insulation circuit 1300 may also be a capacitor.

The second signal processing circuit 1210 drives the gate of the target transistor MO, by controlling states of the drivers DRV1 and DRV2 in accordance with the control signal Dout. When the gate of the target transistor MO is driven, the gate voltage of the target transistor MO is controlled, and the state of the target transistor MO is set to ON or OFF. The driver DRV1 has transistors MH1 and ML1 connected to each other in series. The driver DRV2 has transistors MH2 and ML2 connected to each other in series. The transistors MH1 and MH2 are each a P-channel type MOSFET, while the transistors ML1 and ML2 are each an N-channel type MOSFET. Each source of the transistors MH1 and MH2 is connected to the application terminal of the power supply voltage VCC2. Each source of the transistors ML1 and ML2 is connected to the ground GND2. The drains of the transistors MH1 and ML1 are commonly connected to the output terminal OUT1. The drains of the transistors MH2 and ML2 are commonly connected to the output terminal OUT2.

The second signal processing circuit 1210 is connected to each gate of the transistors MH1, ML1, MH2 and ML2, and sets the transistors MH1, ML1, MH2 and ML2 separately to ON or OFF, by separately controlling the gate voltages of the transistors MH1, ML1, MH2 and ML2. On the basis of the control signal Dout and a signal supplied from the temperature determination circuit 1220 (details will be described later), the second signal processing circuit 1210 sets the states of the drivers DRV1 and DRV2 separately, to be an output high state, an output low state, or a both OFF state (Hi-Z state). In the output high state of the driver DRV1, the transistor MH1 is ON, and the transistor ML1 is OFF. In the output low state of the driver DRV1, the transistor MH1 is OFF, and the transistor ML1 is ON. In the both OFF state of the driver DRV1, the transistors MH1 and ML1 are both OFF. In the output high state of the driver DRV2, the transistor MH2 is ON, and the transistor ML2 is OFF. In the output low state of the driver DRV2, the transistor MH2 is OFF, and the transistor ML2 is ON. In the both OFF state of the driver DRV2, the transistors MH2 and ML2 are both OFF.

When the state of the driver DRV1 is the output high state, positive charges are supplied to the gate of the target transistor MO from the application terminal of the power supply voltage VCC2, via the transistor MH1, the output terminal OUT1, the diode 1513, and the resistor 1511, and thus the gate voltage of the target transistor MO is increased to the power supply voltage VCC2 as an upper limit. When the state of the driver DRV1 is the output low state, positive charges are pulled into the ground GND2 from the gate of the target transistor MO, via the resistor 1512, the diode 1514, the output terminal OUT1, and the transistor ML1, and thus the gate voltage of the target transistor MO is decreased to the potential of the ground GND2 as a lower limit. In this way, the driver DRV1 performs input and output of charges from and to the gate of the target transistor MO via the output terminal OUT1 and the resistor circuit 1510, so as to drive the gate of the target transistor MO (controls the gate voltage). When the state of the driver DRV1 is the both OFF state, current is not generated between the driver DRV1 and the gate of the target transistor MO.

When the state of the driver DRV2 is the output high state, positive charges are supplied to the gate of the target transistor MO from the application terminal of the power supply voltage VCC2 via the transistor MH2, the output terminal OUT2, the diode 1523, and the resistor 1521, and thus the gate voltage of the target transistor MO is increased to the power supply voltage VCC2 as an upper limit. When the state of the driver DRV2 is the output low state, positive charges are pulled into the ground GND2 from the gate of the target transistor MO via the resistor 1522, the diode 1524, the output terminal OUT2, and the transistor ML2, and thus the gate voltage of the target transistor MO is decreased to the potential of the ground GND2 as a lower limit. In this way, the driver DRV2 performs input and output of charges from and to the gate of the target transistor MO via the output terminal OUT2 and the resistor circuit 1520, so as to drive the gate of the target transistor MO (controls the gate voltage). When the state of the driver DRV2 is the both OFF state, current is not generated between the driver DRV2 and the gate of the target transistor MO.

In the following description, a group of the drivers DRV1 and DRV2 is referred to as a driver group. FIG. 14 illustrates a plurality of states that the driver group can have. The second signal processing circuit 1210 can set the state of the driver group to any one of states ST_H1, ST_L1, ST_H2, ST_L2, ST_Z, ST_HH, and ST_LL.

In the state ST_H1, the driver DRV1 is in the output high state, and the driver DRV2 is in the both OFF state. In the state ST_L1, the driver DRV1 is in the output low state, and the driver DRV2 is in the both OFF state.

In the state ST_H2, the driver DRV1 is in the both OFF state, and the driver DRV2 is in the output high state. In the state ST_L2, the driver DRV1 is in the both OFF state, and the driver DRV2 is in the output low state.

In the state ST_Z, the drivers DRV1 and DRV2 are both in the both OFF state. In the state ST HH, the drivers DRV1 and DRV2 are both in the output high state. In the state ST_LL, the drivers DRV1 and DRV2 are both in the output low state.

The power supply voltage VCC2 is higher than the gate threshold value voltage of the target transistor MO. For this reason, by setting the state of the driver group to the state ST_H1, ST_H2, or ST_HH, the target transistor MO can be switched from OFF state to ON state, or the target transistor MO can be maintained in ON state. Alternatively, by setting the state of the driver group to the state ST_L1, ST_L2, or ST_LL, the target transistor MO can be switched from ON state to OFF state, or the target transistor MO can be maintained in OFF state.

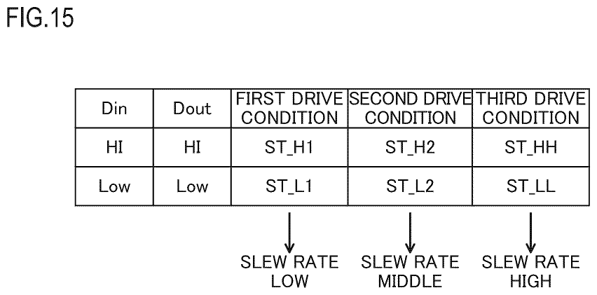

The secondary side circuit 1200 can drive the gate of the target transistor MO in any one of the first to third drive conditions. FIG. 15 illustrates a relationship between the control signals Din and Dout, and the state of the driver group in each drive condition (see also FIG. 14 appropriately).

The secondary side circuit 1200 according to the first drive condition sets the driver group to the state ST_H1 during the high level period of the control signal Dout, and sets the driver group to the state ST_L1 during the low level period of the control signal Dout. In other words, in the first drive condition, the state of the driver group is switched between the states ST L1 and ST_H1 in accordance with the control signal Dout. However, the switching between the states ST_L1 and ST_H1 is a concept including that the state of the driver group is set to the state ST_Z during a minute dead time, in order to prevent generation of a through current during the switching process.

The secondary side circuit 1200 according to the second drive condition sets the driver group to the state ST_H2 during the high level period of the control signal Dout, and sets the driver group to the state ST_L2 during the low level period of the control signal Dout. In other words, in the second drive condition, the state of the driver group is switched between the states ST L2 and ST_H2 in accordance with the control signal Dout. However, the switching between the states ST_L2 and ST_H2 is a concept including that the state of the driver group is set to the state ST_Z during a minute dead time, in order to prevent generation of a through current during the switching process.

The secondary side circuit 1200 according to the third drive condition sets the driver group to the state ST_HH during the high level period of the control signal Dout, and sets the driver group to the state ST_LL during the low level period of the control signal Dout. In other words, in the third drive condition, the state of the driver group is switched between the states ST LL and ST_HH in accordance with the control signal Dout. However, the switching between the states ST_LL and ST_HH is a concept including that the state of the driver group is set to the state ST_Z during a minute dead time, in order to prevent generation of a through current during the switching process.

The transistors MH1 and MH2 have the same structure and electric characteristics. On the other hand, the resistors 1511 and 1521 have different resistance values. For this reason, an increasing slew rate in the first drive condition is different from the increasing slew rate in the second drive condition. The increasing slew rate indicates an increasing rate of the gate voltage of the target transistor MO in the process of increase of the gate voltage of the target transistor MO. A designer of the system SYS can adjust the increasing slew rate in each drive condition in a desired manner, by adjusting each value of the resistors 1511 and 1521. The gate voltage of the target transistor MO is increased to the power supply voltage VCC2 by the driver DRV1 in the first drive condition, or by the driver DRV2 in the second drive condition, or by the drivers DRV1 and DRV2 in the third drive condition.

The transistors ML1 and ML2 have the same structure and electric characteristics. On the other hand, the resistors 1512 and 1522 have different resistance values. For this reason, a decreasing slew rate in the first drive condition is different from the decreasing slew rate in the second drive condition. The decreasing slew rate indicates a decreasing rate of the gate voltage of the target transistor MO in the process of decrease of the gate voltage of the target transistor MO. The designer of the system SYS can adjust the decreasing slew rate in each drive condition in a desired manner, by adjusting each value of the resistors 1512 and 1522. The gate voltage of the target transistor MO is decreased to the voltage of the ground GND2 by the driver DRV1 in the first drive condition, or by the driver DRV2 in the second drive condition, or by the drivers DRV1 and DRV2 in the third drive condition.

In the following description, for specific description, unless otherwise noted, it is supposed that the resistor 1511 has a larger resistance value than the resistor 1521, and the resistor 1512 has a larger resistance value than the resistor 1522, and hence that the slew rates (the increasing slew rate and the decreasing slew rate) in the second drive condition are higher than the slew rates (the increasing slew rate and the decreasing slew rate) in the first drive condition. The slew rates (the increasing slew rate and the decreasing slew rate) are higher in the third drive condition than in the first and second drive condition. In this way, the secondary side circuit 1200 can use the third drive condition, and in the following description, the first and second drive conditions are particularly noted. Note that in the following description, it is supposed that a simply written slew rate indicates the increasing slew rate or the decreasing slew rate.

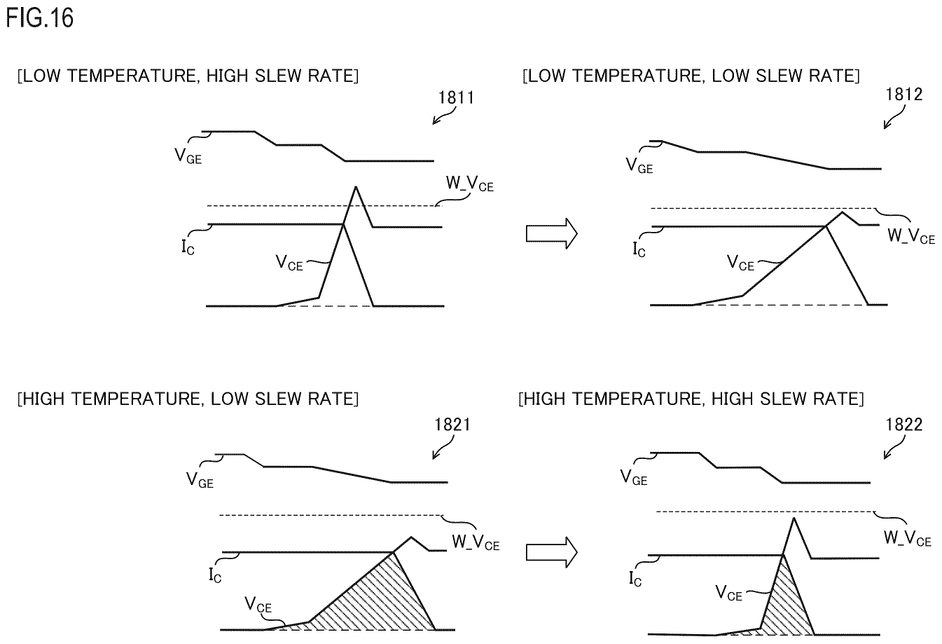

The load LD has an induction component. The load LD may be a coil. In this case, when the target transistor MO is switched from ON state to OFF state, the induction component generates an electromotive force, which causes a surge voltage to be applied between the collector and emitter of the target transistor MO. The level of the surge voltage varies depending on the decreasing slew rate. On the other hand, the withstand voltage of the target transistor MO varies depending on temperature of the target transistor MO. This is described with reference to FIG. 16. The collector current of the target transistor MO is denoted by “Ic”. The collector-emitter voltage of the target transistor MO is denoted by “VCE:”. The gate-emitter voltage of the target transistor MO is denoted by “VGE:”. The withstand voltage between the gate and emitter of the target transistor MO is denoted by “W_VCE”.

In FIG. 16, a graph 1811 indicates schematic waveforms of the current Ic and the voltages Vcr and Vor together with a level of the withstand voltage W_VCE, in a condition where the temperature of the target transistor MO is relatively low and the decreasing slew rate is relatively large. A graph 1812 indicates schematic waveforms of the current Ic and the voltages Vcr and Vor together with a level of the withstand voltage W_VCE, in a condition where the temperature of the target transistor MO is relatively low and the decreasing slew rate is relatively small. The withstand voltage W_VcE decreases along with a decrease in the temperature of the target transistor MO. Therefore, particularly at low temperature, it should be careful about the surge voltage exceeding the withstand voltage. In the condition corresponding to the graph 1811, due to a relatively high slew rate, there is a timing where the collector-emitter voltage VCE exceeds the withstand voltage W_VCE. In contrast, in the condition corresponding to the graph 1812, the slew rate is set to be low, and hence it is avoided that the collector-emitter voltage VCE exceeds the withstand voltage.

In FIG. 16, a graph 1821 indicates schematic waveforms of the current Ic and the voltages Vcr and VGE together with a level of the withstand voltage W_VCE, in a condition where the temperature of the target transistor MO is relatively high and the decreasing slew rate is relatively small. The graph 1822 indicates schematic waveforms of the current Ic and the voltages Vcr and Vor together with a level of the withstand voltage W_VCE, in a condition where the temperature of the target transistor MO is relatively high and the decreasing slew rate is relatively large. In each of the graphs 1821 and 1822, the area of the hatching region indicates an amount of switching loss. The withstand voltage W_Vcr increases along with an increase in the temperature of the target transistor MO. Therefore, at high temperature, it is preferred in many cases to reduce the switching loss rather than the surge voltage exceeding the withstand voltage. In the condition corresponding to the graph 1821, the switching loss becomes relatively large due to the relatively low slew rate, while in the condition corresponding to the graph 1822, the switching loss becomes relatively small due to the relatively high slew rate.

Considering the above facts comprehensively, it is important to set the slew rate to be relatively small when the temperature of the target transistor MO is relatively low, so as to protect the target transistor MO, and it is important to set the slew rate to be relatively large when the temperature of the target transistor MO is relatively high, so as to reduce the switching loss. Only the decreasing slew rate is noted in FIG. 16, but the increasing slew rate also has an appropriate value that is different depending on the temperature of the target transistor MO.

It is also possible to consider a reference method in which a microcomputer (that can be the MPU 1400) capable of communicating with the signal transmission device 1000 is disposed, and the microcomputer instructs the signal transmission device 1000 which drive condition is to be used for driving the target transistor MO in accordance with the temperature of the target transistor MO. However, in the reference method, the microcomputer is essential, and a processing load is applied to the microcomputer every time when the drive condition is set and switched. It is useful if the signal transmission device 1000 can appropriately set or change the drive condition in accordance with the temperature of the target transistor MO, without requiring the microcomputer to issue the instruction.

In order to appropriately set the drive condition, the temperature determination circuit 1220 is disposed in the secondary side circuit 1200 (see FIG. 11). The temperature determination circuit 1220 generates temperature information corresponding to the temperature of the target transistor MO and compares the temperature information with reference information set in advance, so as to output the comparison result to the second signal processing circuit 1210. The second signal processing circuit 1210 sets the drive condition of the gate of the target transistor MO on the basis of the comparison result, so as to adjust the slew rate of the target transistor MO.

The temperature of the target transistor MO is hereinafter referred to as a target temperature Tmp. The system SYS is provided with a temperature measuring element that measures the target temperature Tmp. The temperature determination circuit 1220 detects the target temperature Tmp using the temperature measuring element, so as to generate temperature information. The temperature measuring element is disposed at a position suitable for measuring the temperature of the target transistor MO (the target temperature Tmp). For this reason, the temperature measuring element is disposed at a position close to the target transistor MO. The temperature measuring element may be thermally connected to the target transistor MO. The temperature measuring element can be an arbitrary element as long as its electric characteristics vary in accordance with the target temperature Tmp, and for example, it may be a temperature measuring resistor, a linear resistor, or a thermistor. Alternatively, the temperature determination circuit 1220 and the temperature measuring element constitute a semiconductor temperature sensor. The semiconductor temperature sensor includes a silicon diode as the temperature measuring element and utilizes temperature characteristics of the forward voltage of the diode, so as to detect the target temperature Tmp. Instead of the forward voltage of the diode, the base-emitter voltage of the bipolar transistor may also be utilized for detecting the target temperature Tmp.

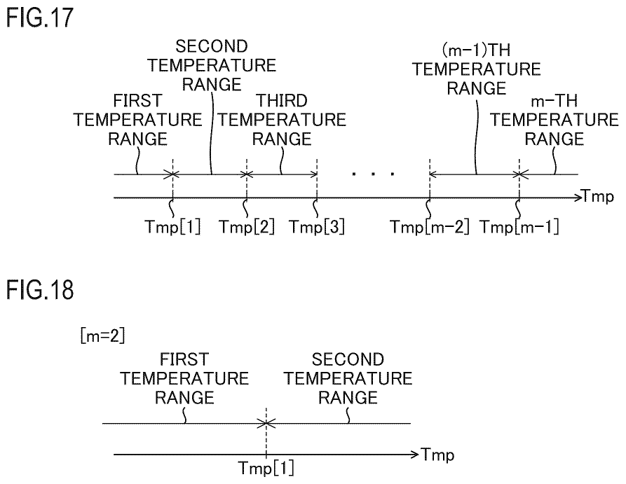

The temperature determination circuit 1220 determines which one of the first to m-th temperature ranges the target temperature Tmp belongs to, on the basis of the temperature information, and outputs a temperature determination signal Sdet indicating the determination result to the second signal processing circuit 1210. In other words, the temperature determination signal Sdet indicates which one of the first to m-th temperature ranges the target temperature Tmp belongs to. Here, m is an arbitrary integer of two or larger. With reference to FIG. 17, the first temperature range is a temperature range lower than or equal to a boundary temperature Tmp[1]. For an arbitrary integer i that satisfies “2≤i≤m−1”, the i-th temperature range is a temperature range that is higher than a boundary temperature Tmp[i−1] and is less than or equal to a boundary temperature Tmp[i]. The m-th temperature range is a temperature range higher than a boundary temperature Tmp[m−1]. The boundary temperatures Tmp[1] to Tmp[m−1] are predetermined (m−1) temperatures, and it is supposed that “Tmp[i]<Tmp[i+1]” holds for an arbitrary natural number i.

In the following description, it is mainly assumed that “m=2” holds, and in the case where “m=2” holds, the temperature determination circuit 1220 determines which one of the first and second temperature ranges the target temperature Tmp belongs to. In the case where “m=2” holds, as illustrated in FIG. 18, the first temperature range is a temperature range lower than or equal to the boundary temperature Tmp[1], and the second temperature range is a temperature range higher than the boundary temperature Tmp[1]. However, it may be possible to understand that the boundary temperature Tmp[1] belongs not to the first temperature range but to the second temperature range.

In the following several embodiments related to the signal transmission device 1000, details and the like of the temperature determination circuit 1220 are described.

### First Embodiment

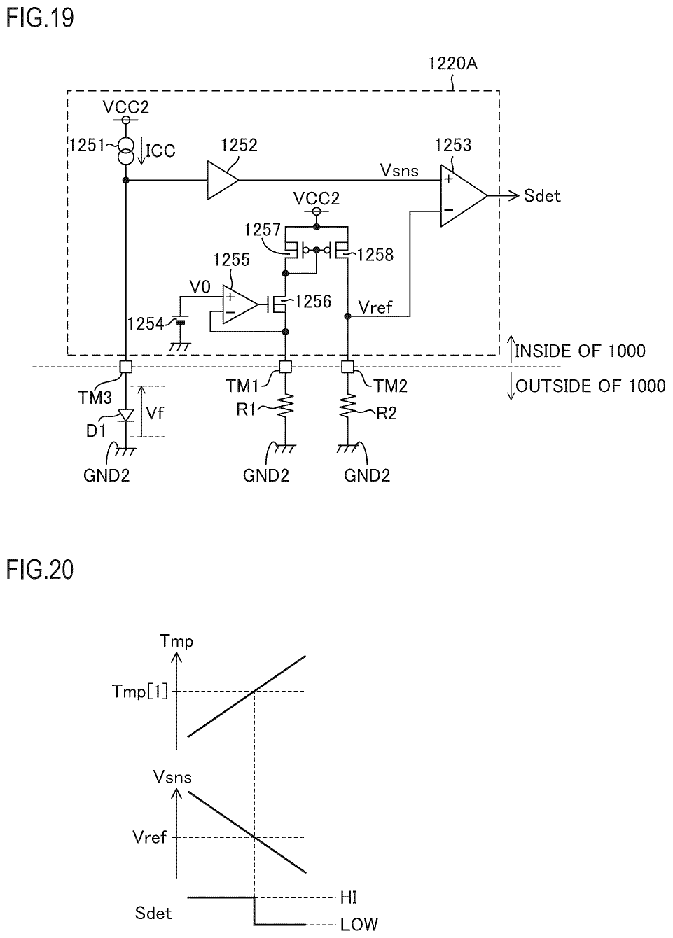

A first embodiment of the signal transmission device 1000 is described. In the first embodiment, “m=2” holds (see FIG. 18). FIG. 19 illustrates a structure of a temperature determination circuit 1220A that is the temperature determination circuit 1220 of the first embodiment, together with its peripheral structure. The signal transmission device 1000 according to the first embodiment has external terminals TM1 to TM3 as three external terminals connected to the secondary side circuit 1200. In FIG. 19, the broken line extending in the left and right direction so as to pass through the external terminals TM1 to TM3 indicates an outer border of the signal transmission device 1000.

In the system SYS (see FIG. 11), a diode D1 and adjusting resistors R1 and R2 are disposed outside of the signal transmission device 1000. The diode D1 is a silicone diode as the temperature measuring element. The temperature determination circuit 1220A includes a constant current source 1251, an amplifier circuit 1252, a comparator 1253, a DC voltage source 1254, an operational amplifier 1255, and transistors 1256 to 1258. The transistor 1256 is an N-channel type MOSFET, and the transistors 1257 and 1258 are each a P-channel type MOSFET. The amplifier circuit 1252, the comparator 1253, the DC voltage source 1254, and the operational amplifier 1255 are driven on the basis of the power supply voltage VCC2 with respect to the potential of the ground GND2.

The anode of the diode D1 is connected to the external terminal TM3, and the cathode of the diode D1 is connected to the ground GND2. A first terminal of the adjusting resistor R1 is connected to the external terminal TM1, and a second terminal of the adjusting resistor R1 is connected to the ground GND2. A first terminal of the adjusting resistor R2 is connected to the external terminal TM2, and a second terminal of the adjusting resistor R2 is connected to the ground GND2. The constant current source 1251 supplies a constant current ICC from the application terminal of the power supply voltage VCC2 to the external terminal TM3. The constant current ICC flows in the diode D1 as a forward current of the diode D1. The amplifier circuit 1252 is connected to the external terminal TM3, and hence when the constant current ICC flows in the diode D1, a forward voltage Vf generated by the diode D1 is input to the amplifier circuit 1252. The amplifier circuit 1252 amplifies the forward voltage Vf, so as to generate a detection voltage Vsns. The amplifier circuit 1252 has an arbitrary amplification factor. The amplifier circuit 1252 may have an amplification factor of one, and in this case, the amplifier circuit 1252 is a buffer circuit that outputs the forward voltage Vf with low impedance. In any case, the detection voltage Vsns is an analog voltage that is proportional (directly proportional) to the forward voltage Vf. Because the temperature of the diode D1 agrees with the target temperature Tmp, the forward voltage Vf and the detection voltage Vsns decrease along with an increase of the target temperature Tmp, while they increase along with a decrease of the target temperature Tmp. The detection voltage Vsns is an example of the temperature information corresponding to the temperature of the target transistor MO (the target temperature Tmp). The detection voltage Vsns output from the amplifier circuit 1252 is supplied to a non-inverting input terminal of the comparator 1253.

The DC voltage source 1254 generates a predetermined positive DC voltage VO, and supplies the DC voltage VO to a non-inverting input terminal of the operational amplifier 1255. An inverting input terminal of the operational amplifier 1255 is connected to the external terminal TM1. An output terminal of the operational amplifier 1255 is connected to the gate of the transistor 1256. The source of the transistor 1256 is connected to the external terminal TM1. The drain of the transistor 1256 is connected to the drain and gate of the transistor 1257 and the gate of the transistor 1258. Each source of the transistors 1257 and 1258 is applied with the power supply voltage VCC2. The drain of the transistor 1258 and an inverting input terminal of the comparator 1253 are commonly connected to the external terminal TM2. The voltage at the external terminal TM2 is referred to as a reference voltage Vref.

The operational amplifier 1255 controls the gate potential of the transistor 1256 so that the voltage at the external terminal TM1 matches the DC voltage VO. For this reason, a drain current, which has a current value determined by values of the DC voltage VO and the adjusting resistor R1, flows in the transistor 1256, and due to an action of a current mirror circuit constituted of the transistors 1257 and 1258, a current proportional to the drain current of the transistor 1256 flows through the transistor 1258 and the adjusting resistor R2. Then, if a ratio between the drain current of the transistor 1257 and the drain current of the transistor 1258 is 1:1, the reference voltage Vref is expressed by the equation “Vref=R2×VO/R1”. In this equation, R1 and R2 represent resistance values of the adjusting resistors R1, R2, respectively.

The non-inverting input terminal of the comparator 1253 is supplied with the detection voltage Vsns corresponding to the temperature information, and the inverting input terminal of the comparator 1253 is supplied with the reference voltage Vref corresponding to the reference information. The comparator 1253 compares the detection voltage Vsns with the reference voltage Vref, and outputs the temperature determination signal Sdet indicating the comparison result. As described above, “m=2” is assumed in the first embodiment, and hence the temperature determination signal Sdet according to the first embodiment is a binary signal having high level or low level. The comparator 1253 outputs the temperature determination signal Sdet of high level when “Vsns>Vref” holds, while it outputs the temperature determination signal Sdet of low level when “Vsns<Vref” holds. When “Vsns=Vref” holds, the temperature determination signal Sdet has high level or low level. It may be possible that the comparator 1253 has hysteresis characteristics.

The second signal processing circuit 1210 selects one of the drive conditions to be used for driving the gate of the target transistor MO on the basis of the temperature determination signal Sdet and drives the gate of the target transistor MO with the selected drive condition. FIG. 20 schematically illustrates a relationship among the target temperature Tmp, the detection voltage Vsns, and the temperature determination signal Sdet. For simple illustration, FIG. 20 shows that the detection voltage Vsns is linearly changed along with temperature variation of the target temperature Tmp, but reality is different (the same is true in FIG. 22 referred to later). As described above, the forward voltage Vf and the detection voltage Vsns decrease along with an increase of the target temperature Tmp, while they increase along with a decrease of the target temperature Tmp. For this reason, the temperature determination signal Sdet of high level indicates that the target temperature Tmp belongs to the first temperature range of relatively low temperatures, while the temperature determination signal Sdet of low level indicates that the target temperature Tmp belongs to the second temperature range of relatively high temperatures (see also FIG. 18 appropriately). Therefore, when the temperature determination signal Sdet has high level, the second signal processing circuit 1210 drives the gate of the target transistor MO with the first drive condition, so as to control the slew rate to be relatively small (see FIG. 15 and FIG. 16). On the contrary, when the temperature determination signal Sdet has low level, the second signal processing circuit 1210 drives the gate of the target transistor MO with the second drive condition, so as to control the slew rate to be relatively large (see FIG. 15 and FIG. 16).

According to this embodiment, successive instructions from a microcomputer like the above reference method are not necessary, but the signal transmission device 1000 can appropriately set or change the drive condition of the target transistor MO (i.e., the slew rate of the gate voltage of the target transistor MO), in accordance with the temperature of the target transistor MO (the target temperature Tmp).

The designer of the system SYS can freely set the reference voltage Vref by setting values of the adjusting resistors R1 and R2 to desired values. By adjusting the reference voltage Vref, the boundary temperature (Tmp[1]) of the switching between the first and second drive conditions can be freely adjusted. As the adjusting resistors R1 and R2, it is preferred to use the same type of resistors having the same temperature characteristics. In this way, a variation of the reference voltage Vref due to temperature variation can be controlled to be low.

It may be possible that only one of the adjusting resistors R1 and R2 is disposed outside of the signal transmission device 1000, and that the other is built into the signal transmission device 1000. In this case, by adjusting a resistance value of the adjusting resistor disposed outside of the signal transmission device 1000 out of the adjusting resistors R1 and R2, the boundary temperature (Tmp[1]) of the switching between the first and second drive conditions can be adjusted. However, in order to control the variation of the reference voltage Vref due to temperature variation to be low, it is desirable to dispose both the adjusting resistors R1 and R2 outside of the signal transmission device 1000, and to use the same type of resistors as the adjusting resistors R1 and R2.

### Second Embodiment

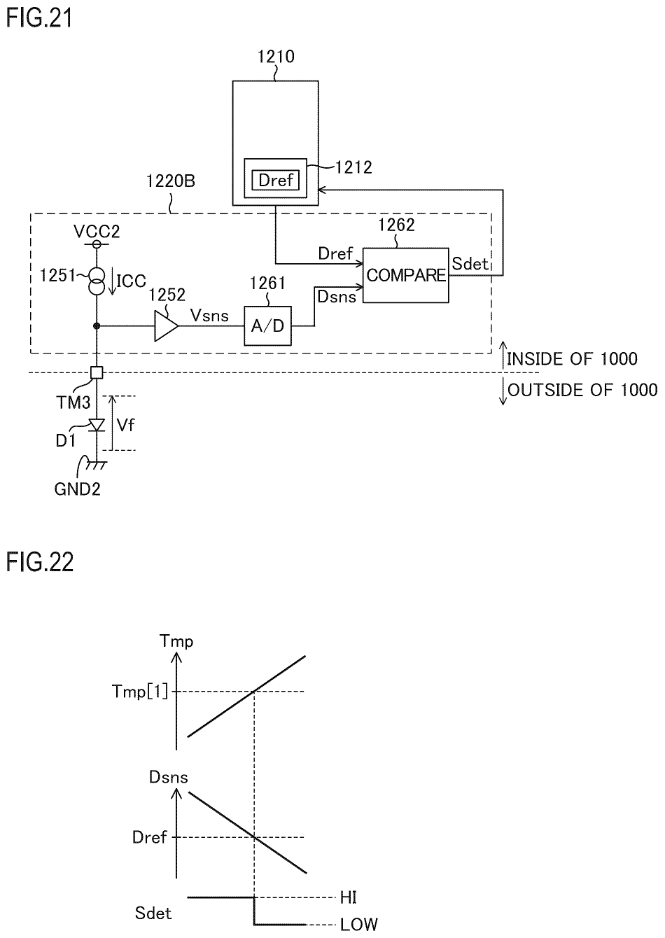

A second embodiment of the signal transmission device 1000 is described. In the second embodiment, “m=2” holds (see FIG. 18). FIG. 21 illustrate a structure of a temperature determination circuit 1220B that is the temperature determination circuit 1220 of the second embodiment, together with its peripheral structure. The signal transmission device 1000 according to the second embodiment has the external terminal TM3 as one external terminal connected to the secondary side circuit 1200. In FIG. 21, the broken line extending in the left and right direction so as to pass through the external terminal TM3 indicates an outer border of the signal transmission device 1000.

In the system SYS (see FIG. 11), the diode D1 is disposed outside of the signal transmission device 1000. The diode D1 is a silicone diode as the temperature measuring element. The temperature determination circuit 1220B includes the constant current source 1251, the amplifier circuit 1252, an AD conversion circuit 1261, and a comparing circuit 1262. The amplifier circuit 1252, the AD conversion circuit 1261, and the comparing circuit 1262 are driven on the basis of the power supply voltage VCC2 with respect to the potential of the ground GND2.

The connection relationship among the diode D1, the external terminal TM3, the ground GND2, the constant current source 1251, and the amplifier circuit 1252, as well as the functions and operations of the diode D1, the constant current source 1251, and the amplifier circuit 1252 are described above in the first embodiment. Therefore, the detection voltage Vsns having the characteristics describe above in the first embodiment is output from the amplifier circuit 1252, as the temperature information corresponding to the temperature of the target transistor MO (the target temperature Tmp). However, in the temperature determination circuit 1220B, the detection voltage Vsns from the amplifier circuit 1252 is supplied to the AD conversion circuit 1261.

The AD conversion circuit 1261 performs an AD conversion process for converting the detection voltage Vsns as an analog voltage into a digital signal. The digital signal obtained by this conversion has a digital value proportional to an analog voltage value of the detection voltage Vsns (hereinafter, referred to as a detected digital value Dsns). The AD conversion circuit 1261 performs the AD conversion process repeatedly at a predetermined period. The execution timing of the AD conversion process may be designated by the second signal processing circuit 1210. The digital signal obtained by the AD conversion process in the AD conversion circuit 1261 has an arbitrary number of bits (i.e., number of bits of the detected digital value Dsns), such as 8 bits, 10 bits, or 12 bits. Because the detection voltage Vsns is proportional to the forward voltage Vf, the detected digital value Dsns decreases along with an increase of the target temperature Tmp, while it increases along with a decrease of the target temperature Tmp. The detected digital value Dans is an example of the temperature information corresponding to the temperature of the target transistor MO (the target temperature Tmp). The detected digital value Dsns is supplied to the comparing circuit 1262.

A memory 1212 is built in the second signal processing circuit 1210. The memory 1212 may be a nonvolatile memory or may be a volatile memory that is classified as a register or the like. The data stored in the memory 1212 includes a reference digital value Dref. The reference digital value Dref is expressed using the same number of bits as the detected digital value Dsns. The reference digital value Dref is an example of the reference information that is used for comparing with the temperature information (the detected digital value Dsns), and the reference digital value Dref identifies the boundary temperature Tmp[1]. The reference digital value Dref is supplied from the second signal processing circuit 1210 to the comparing circuit 1262.

The comparing circuit 1262 compares the detected digital value Dsns with the reference digital value Dref, and outputs the temperature determination signal Sdet indicating the comparison result. As described above, “m=2” is assumed in the second embodiment, and therefore the temperature determination signal Sdet according to the second embodiment is a binary signal having high level or low level. The comparing circuit 1262 outputs the temperature determination signal Sdet of high level when “Dsns>Dref” holds, while it outputs the temperature determination signal Sdet of low level when “Dsns<Dref” holds (see FIG. 22). When “Dsns=Dref” holds, the temperature determination signal Sdet has high level or low level. It may be possible that the comparing circuit 1262 has hysteresis characteristics. The AD conversion circuit 1261 supplies the latest detected digital value Dsns to the comparing circuit 1262 every time when it performs the AD conversion process. The comparing circuit 1262 outputs the temperature determination signal Sdet corresponding to the latest detected digital value Dsns.

The second signal processing circuit 1210 selects one of the drive conditions to be used for driving the gate of the target transistor MO, on the basis of the temperature determination signal Sdet, and drives the gate of the target transistor MO with the selected drive condition. FIG. 22 schematically illustrates a relationship among the target temperature Tmp, the detected digital value Dsns, and the temperature determination signal Sdet. As described above, the forward voltage Vf and the detected digital value Dsns decrease along with an increase of the target temperature Tmp, while they increase along with a decrease of the target temperature Tmp. For this reason, the temperature determination signal Sdet of high level indicates that the target temperature Tmp belongs to the first temperature range of relatively low temperatures, while the temperature determination signal Sdet of low level indicates that the target temperature Tmp belongs to the second temperature range of relatively high temperatures (see also FIG. 18 appropriately). Therefore, when the temperature determination signal Sdet has high level, the second signal processing circuit 1210 drives the gate of the target transistor MO with the first drive condition, so as to control the slew rate to be relatively small (see FIG. 15 and FIG. 16). On the contrary, when the temperature determination signal Sdet has low level, the second signal processing circuit 1210 drives the gate of the target transistor MO with the second drive condition, so as to control the slew rate to be relatively large (see FIG. 15 and FIG. 16).

According to this embodiment, successive instructions from a microcomputer like the above reference method are not necessary, but the signal transmission device 1000 can appropriately set or change the drive condition of the target transistor MO (i.e., the slew rate of the gate voltage of the target transistor MO), in accordance with the temperature of the target transistor MO (the target temperature Tmp).

The signal transmission device 1000 sets the reference digital value Dref on the basis of a setting signal received from the MPU 1400. A specific procedure is described. When the state where the signal transmission device 1000 is not supplied with the power supply voltages VCC1 and VCC2 is transferred to the state where the signal transmission device 1000 is supplies with the power supply voltages VCC1 and VCC2, an initial sequence operation is first performed in the signal transmission device 1000. In the initial sequence operation, initialization or the like of each circuit in the signal transmission device 1000 is performed, and the first signal processing circuit 1110 waits for receiving the setting signal from the MPU 1400.

The setting signal is a command signal sent from the MPU 1400 to the signal transmission device 1000 in accordance with the SPI protocol, and is received by the first signal processing circuit 1110 via the communication terminal group CTG. The setting signal includes information of the reference digital value Dref. The setting signal is a command signal that instructs the memory 1212 to write the reference digital value Dref. In the initial sequence operation, when the setting signal is received by the first signal processing circuit 1110, the first signal processing circuit 1110 sends the reference digital value Dref included in the setting signal to the second signal processing circuit 1210 via the insulation circuit 1300. In the initial sequence operation, the second signal processing circuit 1210 allows the memory 1212 to write and store the reference digital value Dref received from the first signal processing circuit 1110. The first signal processing circuit 1110 is sufficient to send the reference digital value Dref having a predetermined bit length to the second signal processing circuit 1210, one bit at a time using the insulation circuit 1300, and the method for sending information using the pulse transformer (1310, 1320) is known.

Before the initial sequence operation is completed, an input signal to the signal input terminal SIN is invalid, and an input signal from the MPU 1400 to the signal input terminal SIN functions as the control signal Din only after the initial sequence operation, which includes writing of the reference digital value Dref to the memory 1212, is completed. Therefore, only after the initial sequence operation is completed, the control signal Dout is generated from the control signal Din by cooperation between the signal processing circuits 1110 and 1210 as illustrated in FIG. 13, and the gate of the target transistor MO is driven by the driver DRV1 or DRV2 in accordance with the control signal Dout. During execution of the initial sequence operation, the second signal processing circuit 1210 may set the state of the driver group to the state ST_L1, ST_L2, or ST_LL.

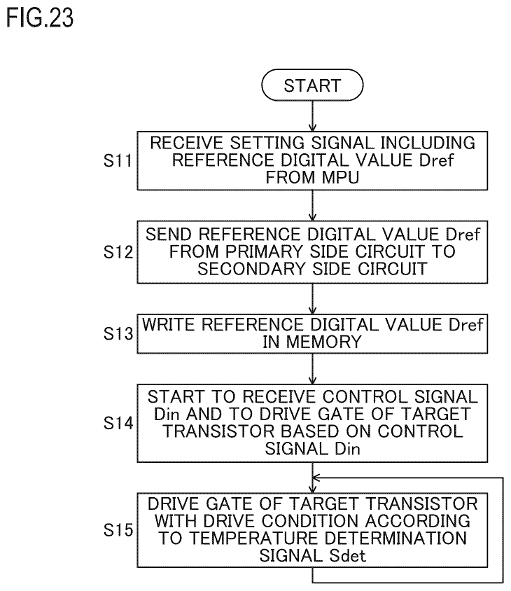

FIG. 23 illustrates an operational flowchart of the signal transmission device 1000 according to the second embodiment. When starting supply of the power supply voltages VCC1 and VCC2 to the signal transmission device 1000, the initial sequence operation is performed, and Steps S11 to S13 are sequentially executed in the initial sequence operation. In Step S11, the first signal processing circuit 1110 receives the setting signal including the reference digital value Dref from the MPU 1400. Next in Step S12, the first signal processing circuit 1110 sends the reference digital value Dref included in the setting signal to the second signal processing circuit 1210 via the insulation circuit 1300. After that, in Step S13, the second signal processing circuit 1210 allows the memory 1212 to write and store the reference digital value Dref received from the first signal processing circuit 1110. When the initial sequence operation is completed after Step S13, the process proceeds to Step S14. In Step S14, the first signal processing circuit 1110 starts to receive the control signal Din from the MPU 1400, and the second signal processing circuit 1210 starts to drive the gate of the target transistor MO on the basis of the control signal Din (in detail, on the basis of the control signal Dout generated from the control signal Din). The drive condition of the gate of the target transistor MO is according to the temperature determination signal Sdet. After that, the gate of the target transistor MO is driven with the drive condition according to the temperature determination signal Sdet (Step S15).

The designer of the system SYS can freely set the reference digital value Dref using the setting signal. By adjusting the reference digital value Dref, the boundary temperature (Tmp[1]) of the switching between the first and second drive conditions can be freely adjusted.

### Third Embodiment

A third embodiment of the signal transmission device 1000 is described. In the first and second embodiments, “m=2” holds, and hence the slew rate is adjusted (variably set) in two steps. However, as described above, m may be an arbitrary integer of two or more. For instance, if “m=3” holds, the temperature determination signal Sdet is a 2-bit signal having a value of “0”, “1” or “2”. In this case, the temperature determination signals Sdet of “0”, “1”, and “2” indicate that the target temperature Tmp belongs to the first, second, and third temperature ranges, respectively.

For instance, if “m=3” holds in the first embodiment, the temperature determination circuit 1220A generates the reference voltages Vref1 and Vref2 having different voltage values as the two reference voltages Vref (here, “Vref1<Vref2” holds), and it is sufficient to configure the temperature determination circuit 1220A so that when “Vref2≤Vsns” holds, the temperature determination signal Sdet has a value of “0”, and that when “Vref1≤Vsns<Vref2” hold, the temperature determination signal Sdet has a value of “1”, and that when “Vsns<Vref1” holds, the temperature determination signal Sdet has a value of “2” (e.g., it is sufficient to configure the comparator 1253 as a window comparator). In this case, it is sufficient that the second signal processing circuit 1210 drives the gate of the target transistor MO using the drivers DRV1 and DRV2, with the first drive condition when “Sdet=0” holds, or with the second drive condition when “Sdet=1” holds, or with the third drive condition when “Sdet=2” holds.

Similarly, for example, when “m=3” holds in the second embodiment, it is sufficient that the memory 1212 holds the reference digital values Dref1 and Dref2 as the two different reference digital values Dref (here, “Dref1<Dref2” holds). It is supposed that the reference digital values Dref1 and Dref2 are included in the setting signal described above. Further, it is sufficient to configure the temperature determination circuit 1220B so that when “Dref2<Dsns” holds, the temperature determination signal Sdet has a value of “0”, and that when “Dref1<Dsns<Dref2” holds, the temperature determination signal Sdet has a value of “1”, and that when “Dsns<Dref1” holds, the temperature determination signal Sdet has a value of “2”. In this case, it is sufficient that the second signal processing circuit 1210 drives the gate of the target transistor MO using the drivers DRV1 and DRV2, with the first drive condition when “Sdet=0” holds, or with the second drive condition when “Sdet=1” holds, or with the third drive condition when “Sdet=2” holds.

In the system SYS of FIG. 11, the two resistor circuits 1510 and 1520 are disposed as the first and second resistor circuits between the signal transmission device 1000 and the gate of the target transistor MO, and it is also possible to increase the value of m to seven at most by adding a third resistor circuit having the same structure as the resistor circuit 1510. It is also possible to dispose four or more resistor circuits.

### Fourth Embodiment

A fourth embodiment of the signal transmission device 1000 is described. In the fourth embodiment, on the basis of the above description of the first to third embodiments, a modified technique, an application technique, a supplementary note, and the like of the signal transmission device 1000 or the system SYS are described.

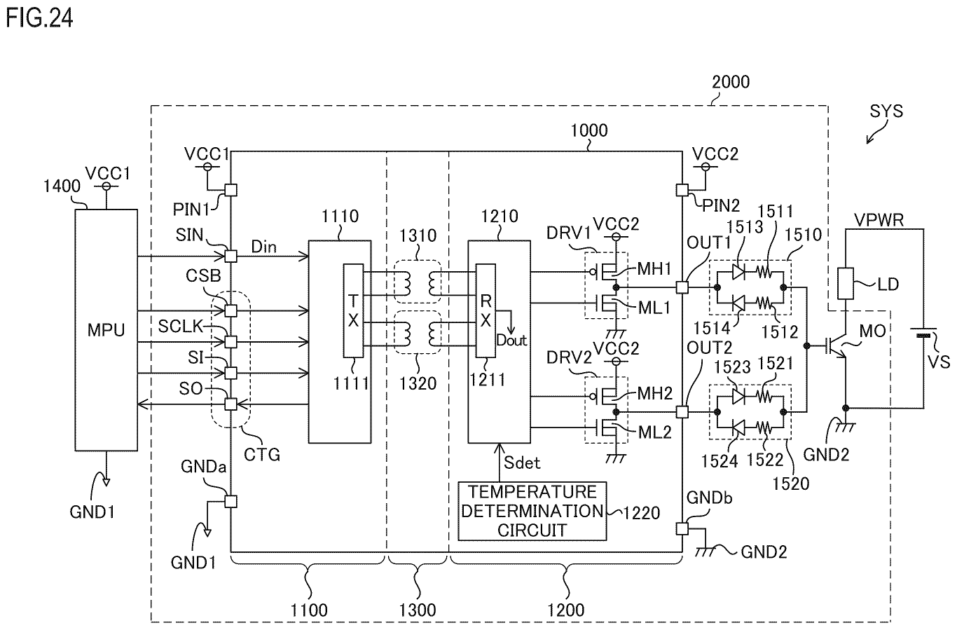

As illustrated in FIG. 24, the system SYS includes a switching device 2000. The switching device 2000 can be understood to be a device obtained by eliminating the MPU 1400, the load LD, and the voltage source VS from the system SYS of FIG. 11, and hence it includes at least the signal transmission device 1000, the target transistor MO, and the resistor circuits 1510 and 1520, as its structural elements. The temperature measuring element such as the diode D1 may be understood to be included in the switching device 2000 as a structural element or may be understood to be disposed outside of the switching device 2000 so as to be connected to the switching device 2000 (the same is true for the adjusting resistors R1 and R2 in the first embodiment).

It may be possible to dispose two switching devices 2000, and to form a half bridge circuit by connecting the target transistor MO in the first switching device 2000 and the target transistor MO in the second switching device 2000 in series. In this case, the same MPU 1400 may be connected to the first and second signal transmission devices 1000. The source potential of the target transistor MO in the i-th switching device 2000 functions as the ground GND2 in the i-th switching device 2000 (here, i-th means first or second).

It may be possible to form a motor drive system having six switching devices 2000, so as to drive a three-phase motor. In this case, the target transistors MO in the first and second switching devices 2000 can be used respectively as an upper arm and a lower arm of the U-phase, and the target transistors MO in the third and fourth switching devices 2000 can be used respectively as an upper arm and a lower arm of the V-phase, and the target transistors MO in the fifth and sixth switching devices 2000 can be used respectively as an upper arm and a lower arm of the W-phase. Further, it is sufficient to control supply currents to a U-phase coil, a V-phase coil, and a W-phase coil of the three-phase motor, by ON-OFF control of the six target transistors MO. In the motor drive system, the same MPU 1400 may be connected to the six signal transmission devices 1000. The source potential of the target transistor MO in the i-th switching device 2000 functions as the ground GND2 in the i-th switching device 2000 (here, i-th means one of first to sixth).

The system SYS of FIG. 11, or an arbitrary system including the system SYS (the above motor drive system or the like) can be mounted in an arbitrary electrical device. The electrical device may be an electrical component mounted in a vehicle such as an automobile, or may be a computer device, a home appliance device, or an industrial device.

For an arbitrary signal or voltage, the relationship between high level and low level can be opposite to that described above, in a form that does not impair the spirit of the above description.

The type of the channel of the field-effect transistor (FET) described in the above embodiment is merely an example. The type of the channel of an arbitrary FET can be changed between the P-channel type and the N-channel type, in a form that does not impair the spirit of the above description.

Unless any inconvenience arises, the above arbitrary transistor may be any type of transistor. For instance, an arbitrary transistor described as a MOSFET can be replaced by a junction type FET, an insulated gate bipolar transistor (IGBT), or a bipolar transistor, unless any inconvenience arises. An arbitrary transistor has a first conductive electrode, a second conductive electrode, and a control electrode. In an FET, one of the first and second conductive electrodes is the drain, while the other is the source, and the control electrode is the gate. In an IGBT, one of the first and second conductive electrodes is the collector, while the other is the emitter, and the control electrode is the gate. In a bipolar transistor that does not belong to IGBT, one of the first and second conductive electrodes is a collector, while the other is an emitter, and the control electrode is the base.

The embodiment of the present disclosure can be appropriately and variously modified within the scope of the technical concept recited in the claims. The above embodiment is merely an example of the embodiment of the present disclosure, and meanings of the present disclosure and terms of the structural elements are not limited to those described in the above embodiment. Specific numeric values shown in the above description are merely examples, and they can be changed to various values as a matter of course.

### Additional Notes

Additional notes are given below for the present disclosure, in which specific structural examples are shown in the above embodiment.

A signal transmission device (see FIG. 11) according to one aspect of the present disclosure is an signal transmission device (1000) disposed between an external device (1400) and a target transistor (MO), and comprises a primary side circuit (1100) configured to receive a primary side control signal (Din) from the external device, a secondary side circuit (1200) configured to drive a gate of the target transistor, and an insulation circuit (1300) configured to insulate in a DC manner between the primary side circuit and the secondary side circuit, while transmitting the primary side control signal as a secondary side control signal (Dout) to the secondary side circuit. The secondary side circuit is configured to control a gate voltage of the target transistor in accordance with the secondary side control signal so as to switch the target transistor between ON and OFF, and to be capable of adjusting a slew rate of change of the gate voltage of the target transistor in multiple steps, and the secondary side circuit generates temperature information according to the temperature of the target transistor, and compares the temperature information with reference information, so as to adjust the slew rate (first structure).

In this way, successive instructions from a microcomputer or the like are not necessary, but the signal transmission device can appropriately set or change the slew rate related to the gate voltage of the target transistor, in accordance with the temperature of the target transistor.

The signal transmission device according to the above first structure (see FIG. 19) may have a structure (second structure), in which the secondary side circuit generates an analog reference voltage (Vref) indicating the reference information and an analog detection voltage (Vsns) indicating the temperature information, and adjusts the slew rate on the basis of a comparison result between the reference voltage and the detection voltage.

The signal transmission device according to the above second structure may have a structure (third structure), in which the secondary side circuit allows the slew rate to be different between a case where the reference voltage is higher than the detection voltage, and a case where the reference voltage is lower than the detection voltage.

The signal transmission device according to the above third structure may have a structure (fourth structure), in which the secondary side circuit generates the reference voltage in accordance with a resistance value of an adjusting resistor (R1, R2) disposed outside of the signal transmission device.

In this way, a designer of the system including the signal transmission device can freely set the reference voltage by setting the resistance value of the adjusting resistor to be a desired value. By adjusting the reference voltage, the slew rate according to the temperature of the target transistor can be optimized.

The signal transmission device according to the above fourth structure (see FIG. 21) may have a structure (fifth structure), in which the secondary side circuit includes a memory (1212) configured to store the reference information as a reference digital value (Dref), generates a detected digital value (Dsns) according to the temperature of the target transistor as the temperature information, and adjusts the slew rate on the basis of a comparison result between the reference digital value and the detected digital value.

The signal transmission device according to the above fifth structure may have a structure (sixth structure), in which the secondary side circuit allows the slew rate to be different between a case where the reference digital value is higher than the detected digital value, and a case where the reference digital value is lower than the detected digital value.

The signal transmission device according to any one of the above first to fifth structures (see FIG. 23) may have a structure (seventh structure), in which the primary side circuit receives the setting signal including the reference digital value from the external device before receiving the primary side control signal, and sends the reference digital value in the setting signal to the secondary side circuit via the insulation circuit, and the secondary side circuit allows the memory to store the reference digital value received from the primary side circuit.

In this way, the designer of the system including the signal transmission device can freely set the reference digital value before driving the target transistor. By adjusting the reference digital value, the slew rate according to the temperature of the target transistor can be optimized.

A switching device (see FIG. 24) according to one aspect of the present disclosure is a switching device (2000) including the signal transmission device (1000) according to any one of the above first to seventh structures, and the target transistor (MO), in which the signal transmission device has a first output terminal (OUT1) and a second output terminal (OUT2), a first resistor circuit (1510) disposed between the first output terminal and a gate of the target transistor, and a second resistor circuit (1520) disposed between the second output terminal and the gate of the target transistor are provided to the switching device, the first resistor circuit and the second resistor circuit each including a resistance component, and the secondary side circuit includes a first driver (DRV1) configured to perform input and output of charges from and to the gate of the target transistor via the first output terminal and the first resistor circuit, and a second driver (DRV2) configured to perform input and output of charges from and to the gate of the target transistor via the second output terminal and the second resistor circuit, and selects the first driver or the second driver to be used for driving the gate of the target transistor, on the basis of the temperature information and the reference information, so as to adjust the slew rate (eighth structure).

What is claimed is:

1. A signal transmission device disposed between an external device and a target transistor, comprising:
a primary side circuit configured to receive a primary side control signal from the external device;
a secondary side circuit configured to drive a gate of the target transistor; and
an insulation circuit configured to insulate in a DC manner between the primary side circuit and the secondary side circuit, while transmitting the primary side control signal as a secondary side control signal to the secondary side circuit, wherein
the secondary side circuit is configured to control a gate voltage of the target transistor in accordance with the secondary side control signal so as to switch the target transistor between ON and OFF, and to be capable of adjusting a slew rate of change of the gate voltage of the target transistor in multiple steps,
the secondary side circuit is configured to be capable of adjusting a slew rate of change of the gate voltage of the target transistor in multiple steps, by controlling a gate voltage of the target transistor in accordance with the secondary side control signal so as to switch the target transistor between ON and OFF, and
the secondary side circuit generates temperature information according to temperature of the target transistor, and compares the temperature information with reference information, so as to adjust the slew rate.

2. The signal transmission device according to claim 1, wherein the secondary side circuit generates an analog reference voltage indicating the reference information and an analog detection voltage indicating the temperature information and adjusts the slew rate on the basis of a comparison result between the reference voltage and the detection voltage.

3. The signal transmission device according to claim 2, wherein the secondary side circuit allows the slew rate to be different between a case where the reference voltage is higher than the detection voltage, and a case where the reference voltage is lower than the detection voltage.

4. The signal transmission device according to claim 2, wherein the secondary side circuit generates the reference voltage in accordance with a resistance value of an adjusting resistor disposed outside of the signal transmission device.

5. The signal transmission device according to claim 1, wherein the secondary side circuit includes a memory configured to store the reference information as a reference digital value, generates a detected digital value according to the temperature of the target transistor as the temperature information, and adjusts the slew rate on the basis of a comparison result between the reference digital value and the detected digital value.

6. The signal transmission device according to claim 5, wherein the secondary side circuit allows the slew rate to be different between a case where the reference digital value is higher than the detected digital value, and a case where the reference digital value is lower than the detected digital value.

7. The signal transmission device according to claim 5, wherein
the primary side circuit receives the setting signal including the reference digital value from the external device before receiving the primary side control signal, and sends the reference digital value in the setting signal to the secondary side circuit via the insulation circuit, and
the secondary side circuit allows the memory to store the reference digital value received from the primary side circuit.

8. A switching device comprising:
the signal transmission device according to claim 1; and
the target transistor, wherein
the signal transmission device has a first output terminal and a second output terminal,
a first resistor circuit disposed between the first output terminal and the gate of the target transistor, and a second resistor circuit disposed between the second output terminal and the gate of the target transistor are provided to the switching device, the first resistor circuit and the second resistor circuit each including a resistance component, and
the secondary side circuit includes a first driver configured to perform input and output of charges from and to the gate of the target transistor via the first output terminal and the first resistor circuit, and a second driver configured to perform input and output of charges from and to the gate of the target transistor via the second output terminal and the second resistor circuit, and selects the first driver or the second driver to be used for driving the gate of the target transistor, on the basis of the temperature information and the reference information, so as to adjust the slew rate.
